(19) United States
(12) Patent Application Publication
(10) Pub. No.: US 2025/0174841 A1
(43) Pub. Date: May 29, 2025

(54) LAMINATED CIRCUIT BODY AND BUSBAR MODULE

(71) Applicant: YAZAKI CORPORATION, Tokyo (JP)

(72) Inventors: Hirotaka Mukasa, Makinohara-shi (JP); Yoshiki Aoshima, Makinohara-shi (JP)

(21) Appl. No.: 19/041,991

(22) Filed: Jan. 30, 2025

Related U.S. Application Data
(63) Continuation of application No. PCT/JP2023/039781, filed on Nov. 2, 2023.

(30) Foreign Application Priority Data
Dec. 5, 2022 (JP) 2022-194335

(51) Int. Cl. H01M 50/519; H01M 50/505; H05K 1/02

(52) U.S. Cl. CPC H01M 50/519; H01M 50/505; H05K 1/0277

(57) ABSTRACT

A laminated circuit body (20) includes: a first circuit body (20A) formed of a flexible substrate having a first wiring pattern; and a second circuit body (20B) formed of a flexible substrate having a second wiring pattern and laminated on the first circuit body (20A). In a laminated portion of the first circuit body (20A) and the second circuit body (20B), an input conductor line (24) and an output conductor line (23) included in the first wiring pattern are conductively connected to each other via a relay conductor line (25) included in the second wiring pattern.

### TECHNICAL FIELD

The present invention relates to a laminated circuit body and a busbar module using the laminated circuit body.

### BACKGROUND ART

In the related art, a busbar module is used, for example, to be assembled to a battery assembly (that is, a battery module in which a plurality of battery cells are stacked and arranged) that is used as a driving power source mounted on an electric vehicle, a hybrid vehicle, or the like (see, for example, Patent Literatures 1 to 3).

As an example, the busbar module described in Patent Literature 1 includes a plurality of busbars and voltage detection lines. The busbars are stacked, and each of the busbars connects a positive electrode and a negative electrode between adjacent battery cells. The voltage detection lines are respectively connected to the plurality of busbars and monitor the battery cells. The voltage detection line is configured to bundle a plurality of electric wires. Each of the electric wires has a general structure in which a core wire is covered with an insulating sheath.

### CITATION LIST

### Patent Literature

Patent Literature 1: JP2014-220128A

Patent Literature 2: JP2020-087666A

Patent Literature 3: JP2007-123394A

### SUMMARY OF INVENTION

### Technical Problem

In general, the battery cells constituting the battery assembly expand and contract in a stacking direction due to operating heat associated with charging and discharging, a temperature of an external environment, and the like. As a result, the battery assembly (battery module) is also deformed to expand and contract in the stacking direction of the battery cells. Further, a size of the battery assembly in the stacking direction may generally vary for manufactured battery assemblies (that is, a manufacturing variation may occur) due to an assembly tolerance when the plurality of battery cells are stacked and arranged. Therefore, the busbar module is generally designed to have a certain margin in a length of the voltage detection line in order to cope with such deformation and manufacturing variation of the battery assembly.

However, in the busbar module in the related art described above, for example, when the number of the stacked battery cells is increased for a purpose of increasing a capacity of the battery assembly, the number of the electric wires constituting the voltage detection line also increases. As a result, when the voltage detection line is formed by bundling these many electric wires, a rigidity of the voltage detection line as a whole (and thus a rigidity of the busbar module) increases, and it may be difficult to improve operability (assemblability) of assembling the busbar module to the battery assembly. For the same reason, it may also be difficult for the busbar module to extend and contract to sufficiently cope with the deformation and the manufacturing variation of the battery assembly.

An object of the present invention is to provide a busbar module excellent in assemblability to a battery assembly and adaptability to deformation and a manufacturing variation of the battery assembly, and a laminated circuit body used for the busbar module.

### SOLUTION TO PROBLEM

According to one aspect of the present invention, there is provided a laminated circuit body configure to electrically connect between an input terminal and an output terminal. The laminated circuit body includes:
a first circuit body formed of a flexible substrate having a first wiring pattern; and
a second circuit body formed of a flexible substrate having a second wiring pattern and laminated on the first circuit body, in which
the first wiring pattern includes input conductor lines configured to connect to the input terminal, and output conductor lines configured to connect to the output terminal,
the second wiring pattern includes relay conductor lines, and
in a laminated portion of the first circuit body and the second circuit body, each of the input conductor lines and each of the output conductor lines of the first wiring pattern are conductively connected via each of the relay conductor lines of the second wiring pattern.

According to another aspect of the present invention, there is provided a busbar module to be attached to a battery assembly in which a plurality of single cells are stacked.

The busbar module includes:
the laminated circuit body described above;
a busbar provided as the input terminal and connected to the input conductor lines of the first wiring pattern, the busbar being configured to connect to adjacent electrodes between the plurality of single cells; and
a connector that accommodates the output terminal configured to connect to the output conductor lines of the first wiring pattern, in which
an arrangement order of the output conductor lines in a width direction of the laminated circuit body matches with a magnitude order of potentials of the electrodes connected via the output conductor lines, the relay conductor lines, the input conductor lines, and the busbar.

### BRIEF DESCRIPTION OF DRAWINGS

FIG. 1 is a perspective view showing a state in which a first circuit body and a second circuit body that are included in a laminated circuit body used in a busbar module according to an embodiment are separated from each other;

FIG. 2 is a perspective view showing a busbar module according to the present embodiment;

FIG. 3 is a perspective view showing a battery assembly to which the busbar module shown in FIG. 2 is to be assembled; and

FIG. 4 is a top view of the busbar module shown in FIG. 2.

### DESCRIPTION OF EMBODIMENTS

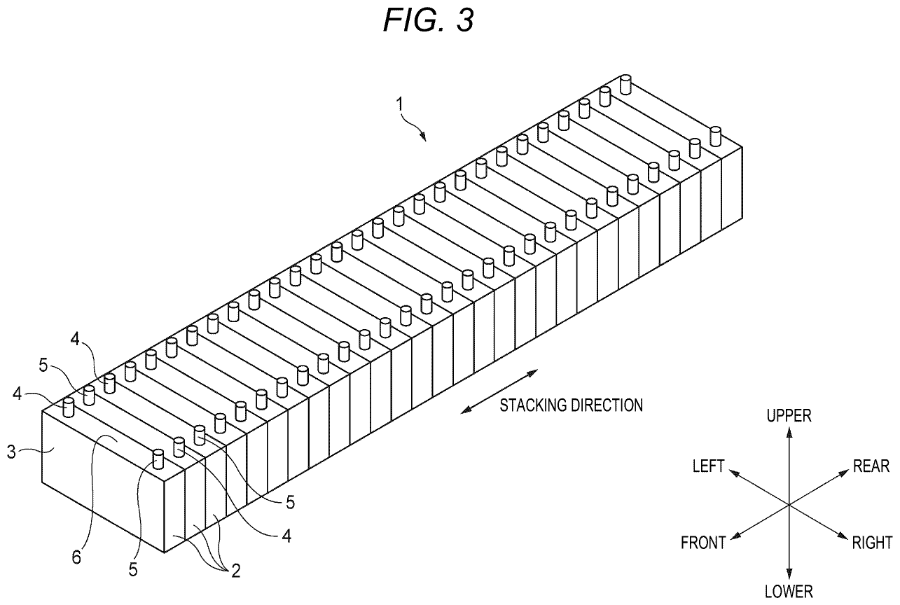

Hereinafter, a busbar module 10 according to an embodiment of the present invention will be described with reference to the drawings. The busbar module 10 according to the present embodiment is used, for example, to be assembled to a long battery assembly 1 (a battery module in which a plurality of single cells are stacked and arranged, see FIG. 3) that is used as a driving power source mounted on an electric vehicle.

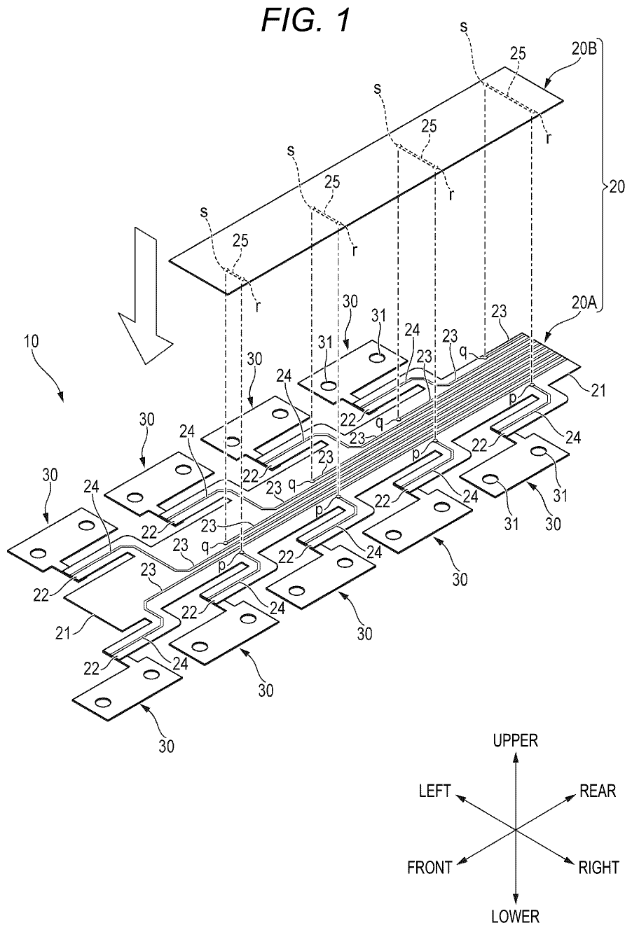

Hereinafter, for convenience of description, “front”, “rear”, “left”, “right”, “upper”, and “lower” are defined as shown in FIG. 1 and the like. A “front-rear direction”, a “left-right direction”, and an “upper-lower direction” are orthogonal to each other. The front-rear direction coincides with a stacking direction (see FIG. 3) of a plurality of single cells 2 included in the battery assembly 1. These directions are defined for convenience of description, and do not necessarily correspond to a front-rear direction, a left-right direction, and an upper-lower direction of a vehicle when the busbar module 10 is mounted on the vehicle.

First, as preparation for describing the busbar module 10, the battery assembly 1 to which the busbar module 10 is to be attached will be described with reference to FIG. 3. As shown in FIG. 3, the battery assembly 1 is formed by stacking, in the front-rear direction, the plurality of rectangular flat plate-shaped single cells 2 each of which extends in the upper-lower direction and the left-right direction. Each of the plurality of single cells 2 includes a battery body 3 having a rectangular flat plate shape, and a positive electrode 4 and a negative electrode 5 protruding upward from both end portions in the left-right direction of an upper face 6 of the battery body 3.

In the battery assembly 1, by making positions in the left-right direction of the positive electrode 4 and the negative electrode 5 of one of the single cells 2 that are adjacent in the front-rear direction opposite to positions in the left-right direction of the positive electrode 4 and the negative electrode 5 of the other single cell 2, the plurality of single cells 2 are stacked such that the positive electrode 4 and the negative electrode 5 are alternately arranged in the front-rear direction at each of a left end portion and a right end portion of an upper face of the battery assembly 1.

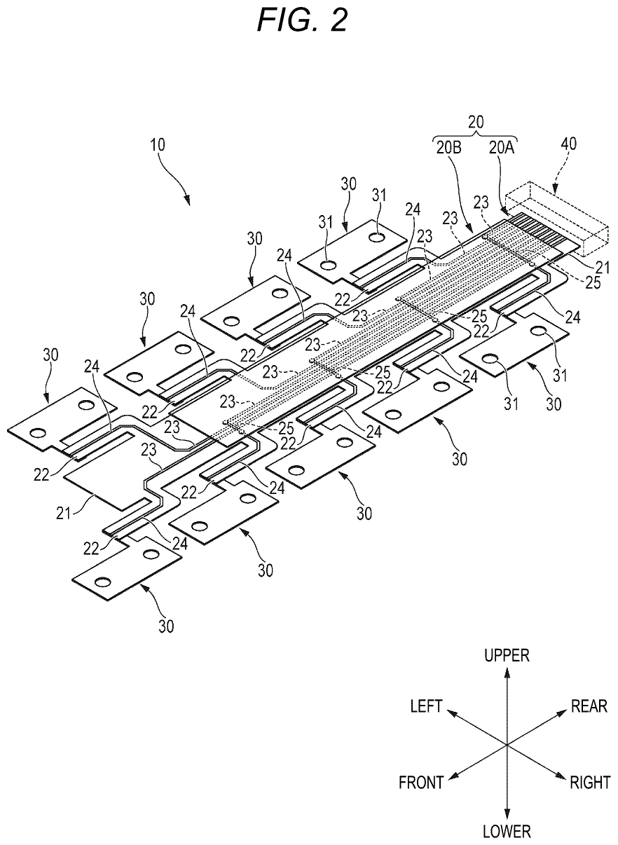

Hereinafter, the busbar module 10 will be described. As shown in FIGS. 1,2, and 4, the busbar module 10 includes a long laminated circuit body 20 extending in the front-rear direction, a plurality of busbars 30 respectively connected to a plurality of branch line portions 22 of the laminated circuit body 20, and a connector 40 (see FIG. 2) connected to a rear end portion of the laminated circuit body 20. A main line portion 21 and the branch line portion 22 of the laminated circuit body 20 are also referred to as a “main line” and a “branch line”, respectively.

The laminated circuit body 20 is formed by laminating a first circuit body 20A and a second circuit body 20B each of which is formed of an easily bendable flexible substrate (FPC). Accordingly, the laminated circuit body 20 (the first circuit body 20A and the second circuit body 20B) also are easily bendable.

As shown in FIG. 1, the first circuit body 20A includes the strip-shaped main line portion 21 extending in the front-rear direction and the plurality of branch line portions 22 extending to branch outward in the left-right direction from a plurality of positions in the front-rear direction of the main line portion 21. The connector 40 is connected to a rear end portion of the main line portion 21 of the first circuit body 20A. The first circuit body 20A has a surface formed of a resin layer except for portions in which contact portions p, q described later are exposed (see FIG. 1), and includes “first wiring patterns”. The first circuit body 20A is a so-called “single-sided flexible substrate (single-sided FPC)” having a single wiring layer, and the “first wiring patterns” are arranged on the single wiring layer. Details of the “first wiring patterns” will be described later.

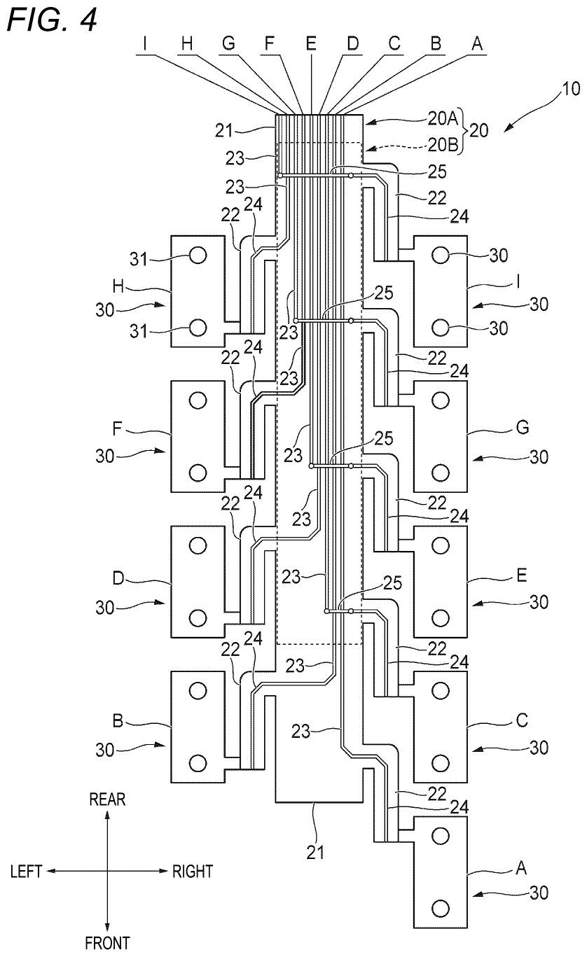

The second circuit body 20B has a strip shape extending in the front-rear direction corresponding to the main line portion 21 of the first circuit body 20A, and is laminated on an upper face of a portion of the first circuit body 20A excluding a front end vicinity region of the main line portion 21 (see FIGS. 2 and 4). The second circuit body 20B A has a surface formed of a resin layer except for portions in which contact portions r, s described later are exposed (see FIG. 1), and includes “second wiring patterns”. The second circuit body 20B is a so-called “single-sided flexible substrate (single-sided FPC)” having a single wiring layer, and the “second wiring patterns” are arranged on the single wiring layer. Details of the “second wiring patterns” will be described later.

Metal busbars 30 are respectively connected to distal end portions of the branch line portions 22 of the first circuit body 20A. As a result, on each of a left side and a right side of the main line portion 21, the plurality of busbars 30 are arranged side by side in a manner of being spaced apart in the front-rear direction (see FIG. 1). Each of the busbars 30 has a substantially rectangular flat plate shape extending in the front-rear direction, and has a pair of front and rear through holes 31. An interval in the front-rear direction between the pair of front and rear through holes 31 is equal to an interval in the front-rear direction between the positive electrode 4 and the negative electrode 5 that are adjacent in the front-rear direction in the battery assembly 1.

Hereinafter, the details of the “first wiring patterns” included in the first circuit body 20A and the “second wiring patterns” included in the second circuit body 20B, and a procedure for laminating the second circuit body 20B on the first circuit body 20A will be described. For convenience of description, as shown in FIG. 4, the plurality of (specifically, nine) busbars 30 and a plurality of (nine) reference signs A, B, C, D, E, F, G, H, and I are associated in a manner of one-to-one correspondence. On the right side of the main line portion 21, five busbars 30 corresponding to the reference signs A, C, E, G, and I are arranged in the front-rear direction. On the left side of the main line portion 21, four busbars 30 corresponding to the reference signs B, D, F, and H are arranged in the front-rear direction.

As shown in FIG. 1 and the like, in the first circuit body 20A, as the “first wiring patterns”, output conductor lines 23 and input conductor lines 24 are arranged in the single wiring layer corresponding to the nine busbars 30 (all busbars 30 arranged on the left and right) corresponding to the reference signs A to I. In the second circuit body 20B, as “second wiring patterns”, relay conductor lines 25 are arranged on the single wiring layer corresponding to the four busbars 30 corresponding to the reference signs C, E, G, and I (four busbars 30 excluding the foremost busbar 30 among the five busbars 30 arranged on the right side). Each of the output conductor lines 23, the input conductor lines 24, and the relay conductor lines 25 is a copper conductor extending in a strip shape.

In the first circuit body 20A, the nine output conductor lines 23 corresponding to the busbars 30 denoted by the reference signs A to I are arranged in the left-right direction in an order of the reference signs A to I from the right to the left, and extend in the front-rear direction from a rear end of the main line portion 21 toward a front side along the main line portion 21 (see FIG. 4). A position in the front-rear direction of a front end of each of the nine output conductor lines 23 corresponding to the busbars 30 denoted by the reference signs A to I matches with a position in the front-rear direction of a base portion of corresponding one of the branch line portions 22. Rear end portions of the nine output conductor lines 23 are independently connected to a plurality of (nine) output terminals (not shown) in a manner of one-to-one correspondence. The output terminals are accommodated in the connector 40 (see FIG. 2) that is connected to the rear end portion of the main line portion 21.

In the first circuit body 20A, the nine input conductor lines 24 corresponding to the nine busbars 30 denoted by the reference signs A to I respectively extend along the branch line portions 22 corresponding to the busbars 30 denoted by the reference signs A to I. Each of the nine input conductor lines 24 is connected to corresponding one of the busbars 30 at a distal end portion of corresponding one of the branch line portions 22. The output conductor line 23 and the input conductor line 24 corresponding to one of the five busbars 30 denoted by the reference signs A, B, D, F, and H are directly conductively connected in the main line portion 21. Meanwhile, the output conductor line 23 and the input conductor line 24 corresponding to one of the four busbars 30 denoted by the reference signs C, E, G, and I are not connected in the main line portion 21, and are conductively connected to each other via corresponding one of the relay conductor lines 25 provided in the second circuit body 20B. Ends of the input conductor lines 24 corresponding to the four busbars 30 denoted by the reference signs C, E, G, and I on a side opposite to the busbars 30 are located in the main line portion 21 in the vicinity of the base portion of the corresponding one of the branch line portions 22.

As a result, each of the five busbars 30 corresponding to the reference signs A, B, D, F, and His conductively connected to corresponding one of the output terminals in the connector 40 through corresponding one of the input conductor lines 24 and corresponding one of the output conductor lines 23 in this order. Each of the four busbars 30 corresponding to the reference signs C, E, G, and I is conductively connected to corresponding one of the output terminals in the connector 40 through corresponding one of the input conductor lines 24, corresponding one of the relay conductor lines 25, and corresponding one of the output conductor lines 23 in this order. The connector 40 is connected to an external voltage detection device (not shown). Accordingly, each of the nine busbars 30 corresponding to the reference signs A to I is individually and conductively connected to the external voltage detection device via the connector 40. The details of the “first wiring patterns” included in the first circuit body 20A and the “second wiring patterns” included in the second circuit body 20B have been described above.

Next, the procedure for laminating the second circuit body 20B on the first circuit body 20A will be described. As shown in FIG. 1, on the upper face of the first circuit body 20A, the metal contact portions p that are respectively and conductively connected to ends of the four input conductor lines 24 corresponding to the four busbars 30 denoted by the reference signs C, E, G, and I on a side opposite to the busbars 30 are respectively provided to be exposed at positions immediately above the ends. The metal contact portions q that are respectively and conductively connected to front ends of the four output conductor lines 23 corresponding to the four busbars 30 denoted by reference signs C, E, G, and I are respectively provided to be exposed at positions immediately above the ends. On a lower face of the second circuit body 20B, the metal contact portions r respectively and conductively connected to right ends of the four relay conductor lines 25 that extend in the left-right direction and that correspond to the four busbars 30 denoted by the reference signs C, E, G, and I are respectively provided to be exposed at positions immediately below the right ends corresponding to the four contact portions p provided in the first circuit body 20A. The metal contact portions s respectively and conductively connected to left ends of the four relay conductor lines 25 that extend in the left-right direction and that correspond to the four busbars 30 denoted by the reference signs C, E, G, and I are provided to be exposed at positions immediately below the left ends corresponding to the four contact portions q provided in the first circuit body 20A.

When the second circuit body 20B is to be laminated on the upper face of the first circuit body 20A, first, the second circuit body 20B is placed on an upper face of the main line portion 21 of the first circuit body 20A such that the contact portions p and r corresponding to each other are arranged to face each other in the upper-lower direction and the contact portions q and s corresponding to each other are arranged to face each other in the upper-lower direction. Next, the contact portions p and r corresponding to each other are independently soldered to each other in a one-to-one manner, and the contact portions q and s corresponding to each other are independently soldered to each other in a one-to-one manner.

Typically, the soldering can be performed by a method (so-called pulse heating method) of sandwiching a paste-like solder between the contact portions p and r arranged to face each other in the upper-lower direction and between the contact portions q and s arranged to face each other in the upper-lower direction, then pressing, against a portion to be soldered, a heater chip that can heat the solder to a temperature at which the solder can be melted, and performing the soldering. The soldering may be performed by a reflow soldering method using a heating furnace. The electrical connection between the contact portions p and r corresponding to each other and the electrical connection between the contact portions q and s corresponding to each other may be performed using a conductive adhesive instead of the soldering described above.

As described above, the second circuit body 20B is laminated on the upper face of the first circuit body 20A in a state in which the output conductor line 23 and the input conductor line 24 provided in the first circuit body 20A corresponding to one of the four busbars 30 denoted by the reference signs C, E, G, and I are conductively connected to each other via the corresponding relay conductor line 25 provided in the second circuit body 20B. The procedure for laminating the second circuit body 20B on the first circuit body 20A has been described above.

The busbar module 10 shown in FIGS. 2 and 4 described above is assembled to the upper face of the battery assembly 1 via a resin holder (not shown) such that in the pair of through holes 31 of the busbar 30, “the corresponding positive electrode 4 and the corresponding negative electrode 5 adjacent to each other in the front-rear direction” are inserted. The holder holds the laminated circuit body 20 and the plurality of busbars 30.

In a state in which the assembly of the busbar module 10 to the battery assembly 1 is completed, the busbars 30 conductively connect “the corresponding positive electrode 4 and the corresponding negative electrode 5 adjacent to each other in the front-rear direction”, so that the plurality of single cells 2 constituting the battery assembly 1 are electrically connected in series via the plurality of busbars 30. As a result, potentials of the nine busbars 30 corresponding to the reference signs A to I become higher in the order of the reference signs A to I. As described above, in the first circuit body 20A, the nine output conductor lines 23 corresponding to the busbars 30 denoted by the reference signs A to I are arranged in the left-right direction in the order of the reference signs A to I from the right to the left (see FIG. 4). As described above, in the laminated circuit body 20, an arrangement order of the nine output conductor lines 23 arranged in the first circuit body 20A is replaced, by the relay conductor lines 25 arranged in the second circuit body 20B, with a potential order of the busbars 30 connected to the input conductor line 24 arranged in the first circuit body 20A. Accordingly, as compared with a case in which a plurality of wiring patterns are provided in a multilayer shape in a single circuit body and such replacement is performed, a manufacturing process of the laminated circuit body 20 is less likely to be complicated, and thus a manufacturing cost can be reduced.

In a use state of the battery assembly 1 to which the busbar module 10 has been attached, each of the single cells 2 constituting the battery assembly 1 may expand or contract in the stacking direction (the front-rear direction) due to operating heat associated with charging and discharging, a temperature of an external environment, and the like. As a result, the battery assembly 1 is also deformed to expand and contract in the stacking direction (front-rear direction). Further, a size of the battery assembly 1 in the stacking direction (front-rear direction) may vary for the manufactured battery assemblies 1 (a manufacturing variation may occur) due to an assembly tolerance when the plurality of single cells 2 are stacked and arranged.

In this regard, in the busbar module 10, even when the extension and contraction of the battery assembly 1 in the stacking direction (front-rear direction) due to the thermal deformation of each single cell 2 and the manufacturing variation of the battery assembly 1 occur, the extension and contraction due to the thermal deformation and the manufacturing variation of the battery assembly 1 can be easily absorbed since each branch line portion 22 formed of the flexible substrate is easily bent.

As described above, according to the busbar module 10 of the present embodiment, the first circuit body 20A and the second circuit body 20B formed of the flexible substrates are integrated by electrically connecting the first wiring patterns (the output conductor line 23 and the input conductor line 24) to the second wiring pattern (the relay conductor line 25) at a laminated portion of the first circuit body 20A and the second circuit body 20B. In other words, the input terminal (the busbar 30) and the output terminal (the output terminal in the connector 40) are electrically connected to each other via the input conductor line 24, the relay conductor line 25, and the output conductor line 23 included in the laminated circuit body 20. Accordingly, for example, in a case in which the busbar 30 serving as the input terminal and the output terminal in the connector 40 serving as the output terminal are electrically connected to each other by the laminated circuit body 20, when the battery assembly 1 expands and contracts in the stacking direction due to the thermal deformation of each single cell 2, each busbar 30 can move in the stacking direction of the single cells 2 by bending or the like of the laminated circuit body 20. Similarly, by the bending or the like of the laminated circuit body 20, a variation in a size of the battery assembly 1 in the stacking direction due to the assembly tolerance of the single cells 2 can be absorbed. In other words, the busbar module 10 according to the present embodiment can easily cope with the expansion and contraction and the manufacturing variation of the battery assembly 1. Here, in general, even when the flexible substrate includes a large number of circuit structures, the flexible substrate is easily and flexibly deformed with a much smaller force than an electric wire used in the busbar module in the related art described above. Therefore, assemblability to the battery assembly 1 is improved. Accordingly, the busbar module 10 according to the present embodiment is more excellent in the assemblability to the battery assembly 1 and adaptability to the deformation and the manufacturing variation of the battery assembly 1 than the busbar module in the related art described above.

According to the busbar module 10 of the present embodiment, the arrangement order of the output conductor lines 23 included in the first wiring patterns in the first circuit body 20A can be replaced with any order by the relay conductor lines 25 included in the second wiring patterns (for example, replaced with the potential order of the busbars 30 to each of which the input conductor line 24 included in the first wiring pattern is connected). Accordingly, as compared with a case in which a plurality of wiring patterns are provided in a multilayer shape in a single circuit body and such replacement is performed, a manufacturing process of the busbar module 10 is less likely to be complicated, and thus a manufacturing cost can be reduced.

The first circuit body 20A is a circuit body (for example, the single-sided flexible substrate) having a single wiring layer, and the second circuit body 20B is a circuit body (for example, the single-sided flexible substrate) having a single wiring layer. Accordingly, as described above, the manufacturing cost of the laminated circuit body 20 can be reduced as compared with a case in which the first circuit body 20A and the second circuit body 20B are entirely formed of a circuit body having a plurality of wiring layers.

The present invention is not limited to the embodiment described above, and various modifications can be adopted within the scope of the present invention. For example, the present invention is not limited to the embodiment described above, and modifications, improvements, and the like can be appropriately made. In addition, materials, shapes, sizes, numbers, arrangement positions, or the like of components in the embodiment described above are freely selected and are not limited as long as the present invention can be implemented.

Here, in the embodiment of the present invention described above, there is provided a laminated circuit body (20) configure to electrically connect between an input terminal (30) and an output terminal. The laminated circuit body (20) includes:
a first circuit body (20A) formed of a flexible substrate having a first wiring pattern; and
a second circuit body (20B) formed of a flexible substrate having a second wiring pattern and laminated on the first circuit body, in which
the first wiring pattern includes input conductor lines (24) configured to connect to the input terminal (30), and output conductor lines (23) configured to connect to the output terminal,
the second wiring pattern includes relay conductor lines (25), and
in a laminated portion of the first circuit body (20A) and the second circuit body (20B), each of the input conductor lines (24) and each of the output conductor lines (23) of the first wiring pattern are conductively connected via each of the relay conductor lines (25) of the second wiring pattern.

According to the laminated circuit body having the above configuration, the first circuit body and the second circuit body formed of the flexible substrates are integrated by electrically connecting the first wiring pattern and the second wiring pattern in the laminated portion of the first circuit body and the second circuit body. In other words, the input terminal and the output terminal are electrically connected to each other via the input conductor line, the relay conductor line, and the output conductor line included in the laminated circuit body. Accordingly, for example, in a case in which the busbar serving as the input terminal and the terminal that is in the connector provided in the busbar module and that serves as the output terminal are electrically connected to each other by the laminated circuit body, when the battery assembly expands and contracts in the stacking direction due to the thermal deformation of each single cell, each busbar can move in the stacking direction of the single cells by the bending or the like of the laminated circuit body. Similarly, by the bending or the like of the laminated circuit body, the variation in the size of the battery assembly in the stacking direction due to the assembly tolerance of the single cells can be absorbed. In other words, the laminated circuit body having the present configuration can easily cope with the expansion and contraction and the manufacturing variation of the battery assembly. Here, in general, even when the flexible substrate includes a large number of circuit structures, the flexible substrate is easily and flexibly deformed with a much smaller force than an electric wire used in the busbar module in the related art described above. Therefore, the assemblability to the battery assembly is improved. Accordingly, the laminated circuit body according having the present configuration is more excellent in the assemblability to the battery assembly and the adaptability to the deformation and the manufacturing variation of the battery assembly than an electric wire used for the busbar module in the related art described above.

According to the laminated circuit body having the above configuration, for example, the arrangement order of the output conductor lines included in the first wiring patterns in the first circuit body can be replaced with any order by the relay conductor lines included in the second wiring patterns (for example, replaced with the potential order of the input terminals to each of which the input conductor line included in the first wiring pattern is connected). Accordingly, as compared with a case in which a plurality of wiring patterns are provided in a multilayer shape in a single circuit body and such replacement is performed, the manufacturing process of the laminated circuit body is less likely to be complicated, and thus the manufacturing cost can be reduced.

The first circuit body (20A) may have a single wiring layer, and may be configured such that the first wiring pattern is arranged in the single wiring layer.

The second circuit body (20B) may have a single wiring layer, and may be configured such that the second wiring pattern is arranged in the single wiring layer.

According to the laminated circuit body having the above configuration, the first circuit body is the circuit body (for example, the single-sided flexible substrate) having the single wiring layer, and the second circuit body is the circuit body (for example, the single-sided flexible substrate) having the single wiring layer. Accordingly, as described above, the manufacturing cost of the laminated circuit body can be reduced as compared with a case in which the first circuit body and the second circuit body are entirely formed of a circuit body having a plurality of wiring layers.

Meanwhile, in the embodiment of the present invention described above, a busbar module (10) is a busbar module (10) to be attached to a battery assembly (1) in which a plurality of single cells (2) are stacked, and the busbar module (10) includes:
the laminated circuit body (20) described above;
a busbar (30) provided as the input terminal and connected to the input conductor lines (24) of the first wiring pattern, the busbar (30) being configured to connect to adjacent electrodes (4, 5) between the plurality of single cells (2); and
a connector (40) that accommodates the output terminal configured to connect to the output conductor lines (23) of the first wiring pattern, in which
an arrangement order of the output conductor lines (23) in a width direction of the laminated circuit body (20) matches with a magnitude order of potentials of the electrodes (4, 5) connected via the output conductor lines (23), the relay conductor lines (25), the input conductor lines (24), and the busbar (30).

According to the busbar module having the above configuration, the first circuit body and the second circuit body formed of the flexible substrates are integrated by electrically connecting the first wiring pattern and the second wiring pattern in the laminated portion of the first circuit body and the second circuit body. In other words, the input terminal and the output terminal are electrically connected via the input conductor line, the relay conductor line, and the output conductor line included in the laminated circuit body. Accordingly, for example, in a case in which the busbar serving as the input terminal and the terminal that is in the connector provided in the busbar module and that serves as the output terminal are electrically connected to each other by the laminated circuit body, when the battery assembly expands and contracts in the stacking direction due to the thermal deformation of each single cell, each busbar can move in the stacking direction of the single cells by the bending or the like of the laminated circuit body. Similarly, by the bending or the like of the laminated circuit body, the variation in the size of the battery assembly in the stacking direction due to the assembly tolerance of the single cells can be absorbed. In other words, the busbar module having the present configuration can easily cope with the expansion and contraction and the manufacturing variation of the battery assembly. Here, in general, even when the flexible substrate includes a large number of circuit structures, the flexible substrate is easily and flexibly deformed with a much smaller force than an electric wire used in the busbar module in the related art described above. Therefore, the assemblability to the battery assembly is improved. Accordingly, the busbar module having the present configuration is more excellent in the assemblability to the battery assembly and the adaptability to the deformation and the manufacturing variation of the battery assembly than the busbar module in the related art described above.

According to the busbar module having the above configuration, for example, the arrangement order of the output conductor lines included in the first wiring patterns in the first circuit body can be replaced with any order by the relay conductor lines included in the second wiring patterns (for example, replaced with the potential order of the input terminals to each of which the input conductor line included in the first wiring pattern is connected). Accordingly, as compared with a case in which a plurality of wiring patterns are provided in a multilayer shape in a single circuit body and such replacement is performed, the manufacturing process of the busbar module is less likely to be complicated, and thus the manufacturing cost can be reduced.

The present application is based on a Japanese patent application (Japanese Patent Application No. 2022-194335) filed on Dec. 5, 2022, and the contents thereof are incorporated herein by reference.

### INDUSTRIAL APPLICABILITY

The laminated circuit body and the busbar module according to the present invention are excellent in the assemblability to the battery assembly and the adaptability to the deformation and the manufacturing variation of the battery assembly. The present invention having this effect can be used, for example, to be assembled to a long battery assembly (for example, a battery module in which a plurality of single cells are stacked and arranged) that is used as a driving power source mounted on an electric vehicle. cl REFERENCE SIGNS LIST
1: battery assembly
2: single cell
4: positive electrode (electrode)
5: negative electrode (electrode)
10: busbar module
20: laminated circuit body
20A: first circuit body
20B: second circuit body
23: output conductor line
24: input conductor line
25: relay conductor line
30: busbar (input terminal)
40: connector

1. A laminated circuit body configure to electrically connect between an input terminal and an output terminal, the laminated circuit body comprising:
a first circuit body formed of a flexible substrate having a first wiring pattern; and
a second circuit body formed of a flexible substrate having a second wiring pattern and laminated on the first circuit body, wherein
the first wiring pattern includes input conductor lines configured to connect to the input terminal, and output conductor lines configured to connect to the output terminal,
the second wiring pattern includes relay conductor lines, and
in a laminated portion of the first circuit body and the second circuit body, each of the input conductor lines and each of the output conductor lines of the first wiring pattern are conductively connected via each of the relay conductor lines of the second wiring pattern.

2. The laminated circuit body according to claim 1, wherein
the first circuit body has a single wiring layer, and is configured such that the first wiring pattern is arranged in the single wiring layer, and
the second circuit body has a single wiring layer, and is configured such that the second wiring pattern is arranged in the single wiring layer.

3. A busbar module to be attached to a battery assembly in which a plurality of single cells are stacked, the busbar module comprising:
the laminated circuit body according to claim 1;
a busbar provided as the input terminal and connected to the input conductor lines of the first wiring pattern, the busbar being configured to connect to adjacent electrodes between the plurality of single cells; and
a connector that accommodates the output terminal configured to connect to the output conductor lines of the first wiring pattern, wherein
an arrangement order of the output conductor lines in a width direction of the laminated circuit body matches with a magnitude order of potentials of the electrodes connected via the output conductor lines, the relay conductor lines, the input conductor lines, and the busbar.
